(19) United States
(12) Patent Application Publication
(10) Pub. No.: US 2026/0354026 A1
(43) Pub. Date: Nov. 5, 2026

(54) THERMOELECTRIC DEVICE

(71) Applicant: NATIONAL INSTITUTE FOR MATERIALS SCIENCE, Tsukuba-shi (JP)

(72) Inventors: Fuyuki Ando, Ibaraki (JP); Yasuyuki Oikawa, Ibaraki (JP); Kenichi Uchida, Ibaraki (JP)

(21) Appl. No.: 19/538,855

(22) Filed: Feb. 12, 2026

Related U.S. Application Data
(63) Continuation of application No. PCT/JP2024/029872, filed on Aug. 22, 2024.

(30) Foreign Application Priority Data
Sep. 1, 2023 (JP) 2023-141932

(51) Int. Cl. H10N 15/20

(52) U.S. Cl. CPC H10N 15/20

(57) ABSTRACT

To realize a highly efficient thermoelectric conversion element by efficiently concentrating a heat flow to a thermoelectric material. The thermoelectric device according to the present invention comprises a bulk of thermoelectric material with remanent magnetization (i.e., a bulk thermoelectric permanent magnet); a contact surface for contacting an object; a heat dissipation surface opposite the contact surface across the bulk thermoelectric permanent magnet, and electrode surfaces that sandwich the bulk thermoelectric permanent magnet in a direction different from those of the contact surface and the heat dissipation surface. The present invention is characterized by the fact that the heat dissipation surface is a heat dissipation structure integrally structured with the bulk thermoelectric permanent magnet. Here, the “bulk thermoelectric permanent magnet” is a composite material containing a magnetic material, and is a group of materials that exhibit high thermoelectric performance by exhibiting various transverse and/or longitudinal thermoelectric conversion phenomena. The remanent magnetization of the bulk thermoelectric permanent magnet superimposes a magneto-thermoelectric effect on the thermoelectric material.

### TECHNICAL FIELD

The present invention relates to a thermoelectric device.

### BACKGROUND ART

To improve the efficiency of energy use, it is desirable to commercialize thermoelectric conversion devices that can generate electricity from waste heat and the environment. The thermoelectric conversion device applies a temperature gradient to a thermoelectric material in the device by bringing a contact surface of the device into contact with a heat source, thereby outputting electromotive force generated in the thermoelectric material from an output terminal of the device. Two types of conventional thermoelectric conversion devices exist: a longitudinal thermoelectric conversion device in which the temperature gradient applied to the thermoelectric material and the electromotive force generated in the thermoelectric material are in the same direction (i.e., parallel), and a transverse thermoelectric conversion device in which the temperature gradient applied to the thermoelectric material and the electromotive force generated in the thermoelectric material are perpendicular to each other.

PTL 1 discloses a thermoelectric device constituted by stacking tilted stacks, in which metal layers and thermoelectric material layers are stacked in a tilted manner, in the thickness direction (stacking direction) of the device. The temperature gradient is perpendicular to the stacking plane, and the interface between the metal layer and the thermoelectric material layer is tilted from the stacking direction. The thermoelectric device is constructed by alternately stacking the tilted stacks with opposite tilt directions and electrically connecting them in series.

PTL 2 discloses a thermoelectric conversion element in which a magnetic field is applied to a thermoelectric conversion material with a large Nernst effect to improve the Seebeck coefficient. When the temperature gradient is in the z direction, p-type and n-type thermoelectric conversion material layers are alternately stacked in the x direction across the permanent magnet. The permanent magnet applies a magnetic field in the x direction to each thermoelectric conversion material layer. Each thermoelectric material layer has electrodes on both sides in the x-direction and apart in the z-direction, i.e., on the high temperature side and the low temperature side. A p-type high temperature side electrode is connected to an n-type high temperature side electrode, and a p-type low temperature side electrode to an n-type low temperature side electrode, respectively, to form a series circuit. If the two electrodes are located at the same temperature, only the Nernst effect will be observed. However, by locating the two electrodes at positions separated in the z direction, i.e., on the high temperature side and the low temperature side, it is possible to enjoy the effect of improving the Seebeck coefficient due to the action of the magnetic field. The same applies to the thermoelectric conversion element described in PTL 3.

The thermoelectric conversion device of PTL 1 is a transverse device that generates electromotive force in the direction perpendicular to the temperature gradient, whereas the thermoelectric conversion devices of PTLS 2 and 3 can be regarded as transverse thermoelectric conversion devices in that the electromotive force generated when the electrodes are separated in the y direction is due to the Nernst effect, but these devices are longitudinal since the electromotive force generated when the electrodes are separated in the z direction is due to the Seebeck effect, albeit enhanced by the magnetic field.

### CITATION LIST

### Patent Document

PTL 1: Japanese Patent Application Laid-Open No. 2012-069626
PTL 2: Japanese Patent Application Laid-Open No. 2002-064228
PTL 3: Japanese Patent Application Laid-Open No. 2001-168403

### SUMMARY OF THE INVENTION

### Problems to Be Solved by the Invention

A conventional longitudinal thermoelectric conversion device is configured by connecting a large number of π-type structures in which p-type and n-type thermoelectric materials are connected in series. In a longitudinal thermoelectric conversion device, the temperature gradient and electromotive force of the thermoelectric material are in the same direction. This inevitably means that an electrode, a substrate, etc. are present between the heat source and the thermoelectric material. When a heat dissipation mechanism is provided on the low temperature side, it is provided on the low temperature side rather than the electrode. A problem with a longitudinal thermoelectric conversion device is as follows: as described above, in a longitudinal thermoelectric conversion device, an electrode, a substrate, etc. are interposed between the heat source and the thermoelectric material, and between the thermoelectric material and the heat dissipation mechanism, acting as sources of thermal resistance, so the thermal energy of the heat source cannot be sufficiently supplied to the thermoelectric material, resulting in a small temperature difference applied to the thermoelectric material and preventing the material from fully utilizing its inherent thermoelectric conversion capacity.

On the other hand, a problem with a transverse thermoelectric conversion device is as follows: in a transverse thermoelectric conversion device, the direction of the temperature gradient and the direction of the electromotive force are perpendicular to each other, so there is no need to provide electrodes between the heat source and the thermoelectric material, or between the thermoelectric material and the heat dissipation mechanism. However, even in the case of transverse thermoelectric devices using materials that have high thermoelectric conversion performance due to anomalous Nernst effect or the spin Seebeck effect, the thermoelectric material is configured as a thin film or multilayer film on a substrate, and the thermoelectric material has a lower thermal resistance and a thinner thickness than the substrate, so when configured as a thermoelectric device, there is almost no effective temperature difference in the thermoelectric material.

The present inventors' investigation of PTLS 1, 2, and 3 revealed the following new problems.

As described above, the thermoelectric conversion element disclosed in PTL 1 is a transverse element, with an electrical insulation layer is formed between the tilted stacks (FIG. 2, reference numeral 23). Thermoelectric device 91 is sandwiched between heat sinks 92 and 93 (FIG. 9). In this way, the heat sink and the electrical insulation layer are interposed in the middle of the temperature gradient from high to low temperature, and the temperature difference applied to the thermoelectric material is accordingly reduced. In PTL 1, a tilted stack in which metal and thermoelectric material are obliquely stacked is stacked in the direction of the temperature gradient, thereby preventing voltage loss. In examples employing BiSbTe-based thermoelectric materials, power generation of 25-50 mW was observed, which corresponds to 5.5-11 mW/cm² per unit area.

The same applies to the thermoelectric conversion elements of PTLS 2 and 3. In the stacked thermoelectric conversion material, the p-type high temperature side electrode is connected to the n-type high temperature side electrode and the p-type low temperature side electrode to the n-type low temperature side electrode, respectively, to form a series circuit, so the wiring is formed on or passes through the top and bottom surfaces of the element (FIG. 1). Therefore, the high-temperature and low temperature sides of the thermoelectric material cannot be brought into direct contact with the heat source. Note that FIG. 2B shows a configuration in which the thermoelectric material is longer than the permanent magnet in the temperature gradient direction and is in direct contact with the cooling or heating plate, but by configuring it with only n-type or p-type, no metal wires are wired between the thermoelectric material and the cooling or heating source. In other words, in order to prevent wiring or electrodes from interposing as a source of thermal resistance in the middle of the path of the temperature gradient, a configuration in which p-type and n-type are alternately connected in series cannot be adopted. When the thermoelectric conversion element is viewed in plan view from the direction of the temperature gradient, its area is shared by the thermoelectric conversion material and permanent magnet, which reduces the amount of electricity generated per unit area. If a configuration is adopted in which the thermoelectric material is in direct contact with a cooling or heating plate as shown in FIG. 2B, the heat flow can be relatively concentrated on the thermoelectric conversion material, but in other configurations, the heat flow is directed to the permanent magnet, which reduces the thermal energy supplied to the thermoelectric material.

As discussed above, when the temperature gradient is viewed three-dimensionally, there are two types of heat flow paths: a series heat flow path from the high temperature side to the low temperature side and a parallel heat flow path when viewed in a plane from the direction of the temperature gradient, it was found that the serial heat flow paths have thermal resistance sources such as electrodes inserted in series, while the parallel heat flow paths have materials such as permanent magnets that do not directly contribute to thermoelectric conversion inserted in parallel, which poses the issue of reducing the heat flow through the thermoelectric material.

An object of the present invention is to efficiently concentrate a heat flow on a thermoelectric material, thereby realizing a highly efficient thermoelectric conversion element.

### Means for Solving Problems

According to a first embodiment, as follows.

That is, a first embodiment of the present invention is a thermoelectric device, which comprises: a bulk of thermoelectric material with remanent magnetization (i.e., a bulk thermoelectric permanent magnet); a contact surface for contacting an object; a heat dissipation surface opposite the contact surface across the bulk; and electrode surfaces that sandwich the bulk in a direction different from those of the contact surface and the heat dissipation surface, wherein the heat dissipation surface is a heat dissipation structure integrally structured with the bulk. Here, the “bulk thermoelectric permanent magnet” is a composite material containing a magnetic material, and is a group of materials that exhibit high thermoelectric performance by exhibiting various transverse and/or longitudinal thermoelectric conversion phenomena. The remanent magnetization of the bulk thermoelectric permanent magnet superimposes a magneto-thermoelectric effect on the thermoelectric material. In this specification, the “bulk thermoelectric permanent magnet” may be simply referred to as “bulk of thermoelectric material” or even simply “bulk. The general term “bulk,” which does not refer to bulk thermoelectric permanent magnets, is a mass that cannot be defined numerically in size but is distinct from a thin film or powder.

According to a second embodiment, as follows.

That is, the thermoelectric device described in the first embodiment above, wherein the remanent magnetization desirably has a component perpendicular to the contact surface.

According to a third embodiment, as follows.

That is, the thermoelectric device described in the first or second embodiment above, wherein the heat dissipation structure has a surface area that is at least twice the area of the heat dissipation surface viewed in plan view.

According to a fourth embodiment, as follows.

That is, the thermoelectric device described in any of the first to three embodiments above, wherein the contact surface is a surface of the bulk.

According to a fifth embodiment, as follows.

That is, the thermoelectric device described in any of the first to fourth embodiments above, wherein the bulk consists of a plurality of unit structures electrically isolated and arranged in the direction different from those of the contact surface, the heat dissipation surface and the electrode surface, the plurality of unit structures being electrically connected to each other at the electrode surface.

According to a sixth embodiment, as follows.

That is, the thermoelectric device described in the fifth embodiment above, wherein the heat dissipation structure is unevenness of the unit structure.

According to a seventh embodiment, as follows.

That is, the thermoelectric device described in the fifth or sixth embodiment above, wherein the unit structure has at least two types of thermoelectric materials stacked in a direction inclined relative to the direction perpendicular to the electrode surface, and one of the at least two thermoelectric materials is a magnetic material.

### Effect of the Invention

The effect to be produced by the above-described embodiment will be briefly described below.

In other words, a heat flow can be efficiently concentrated on the thermoelectric material, thereby realizing a highly efficient thermoelectric conversion element.

### BRIEF DESCRIPTION OF THE DRAWINGS

FIG. 1 is an explanatory diagram schematically illustrating a basic configuration of a thermoelectric device according to the present invention.

FIG. 2 is an explanatory diagram schematically illustrating an embodiment of a thermoelectric device according to the present invention.

FIG. 3 is an explanatory diagram illustrating an example of a thermoelectric device according to the present invention.

FIG. 4 is an explanatory diagram of remanent magnetization.

FIG. 5 is a graph showing the measurement results of the power generation performance of the bulk thermoelectric module fabricated as Example 1.

FIG. 6 is a graph showing the measurement results of the power generation performance of the bulk thermoelectric module fabricated as Example 2.

### DETAILED DESCRIPTION OF THE INVENTION

### 1. Overview of Embodiment

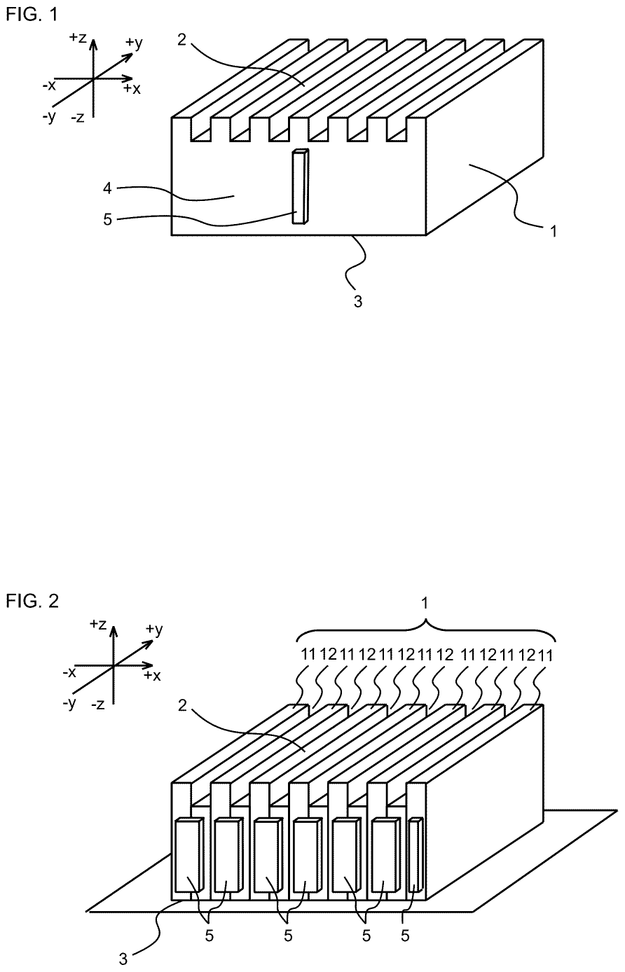

First, an overview of a representative embodiment disclosed in the present application will be given. Reference signs in the drawings that are referred to in parentheses in the outline description of representative embodiment are merely illustrative of what is included in the concept of the components to which they refer.
[1] Thermoelectric device with heat dissipation structure integrated into bulk thermoelectric material (FIG. 1)

A representative embodiment disclosed in this application is a thermoelectric device, which comprises: a bulk of thermoelectric material with remanent magnetization (i.e., a bulk thermoelectric permanent magnet) (1); a contact surface (3) for contacting an object; a heat dissipation surface (2) opposite the contact surface across the bulk; and electrode surfaces (4) that sandwich the bulk in a direction different from those of the contact surface and the heat dissipation surface, wherein the heat dissipation surface is a heat dissipation structure integrally structured with the bulk.

This allows the heat flow to be efficiently concentrated on the thermoelectric material, thereby realizing a highly efficient thermoelectric conversion element. In addition, remanent magnetization makes it easy to bring the contact surface into close contact with magnetic materials such as iron.
[2] Remanent magnetization perpendicular to contact surface

The thermoelectric device described in [1], in which the remanent magnetization has a component perpendicular to the contact surface.

This allows for stronger adhesion of the contact surface to magnetic materials such as iron. Even if the remanent magnetization were completely parallel to the contact surface, the adhesive force would be reduced but would not be completely eliminated, so it would be still possible to bring the thermoelectric device (1) into close contact with a magnetic material such as iron.
[3] Heat dissipation structure

The thermoelectric device described in [1] or [2], in which the heat dissipation structure has a surface area that is at least twice the area of the heat dissipation surface viewed in plan view. When the heat dissipation structure comes into contact with air, water, or other fluid, the heat transfer coefficient is increased, enabling efficient heat dissipation.

This allows direct heat dissipation from the bulk thermoelectric material without going through an electrode, a substrate, a heat sink, etc.
[4] Contact surface is part of bulk thermoelectric material

The thermoelectric device according to any one of [1] to [3], in which the contact surface is a surface of the bulk.

This allows direct heat dissipation from the bulk thermoelectric material without going through an electrode, a substrate, a heat sink, etc. When adhering to a flat object, the contact surface of the bulk thermoelectric material can be made flat and adhered to, thereby lowering the thermal resistance and heating the object efficiently.
[5] Stacking of unit structures (FIG. 2)

The thermoelectric device according to any one of [1] to [4], in which the bulk consists of a plurality of unit structures (11, 12) electrically isolated and arranged in the direction different from those of the contact surface, the heat dissipation surface and the electrode surface, the plurality of unit structures being electrically connected to each other at the electrode surface.

This allows multiple thermoelectric materials to be electrically connected in series to increase the output voltage.
[6] Configure heat dissipation structure by unevenness formed by lengths of stacked unit structures

The thermoelectric device described in [5], in which the heat dissipation structure is unevenness of the unit structure.

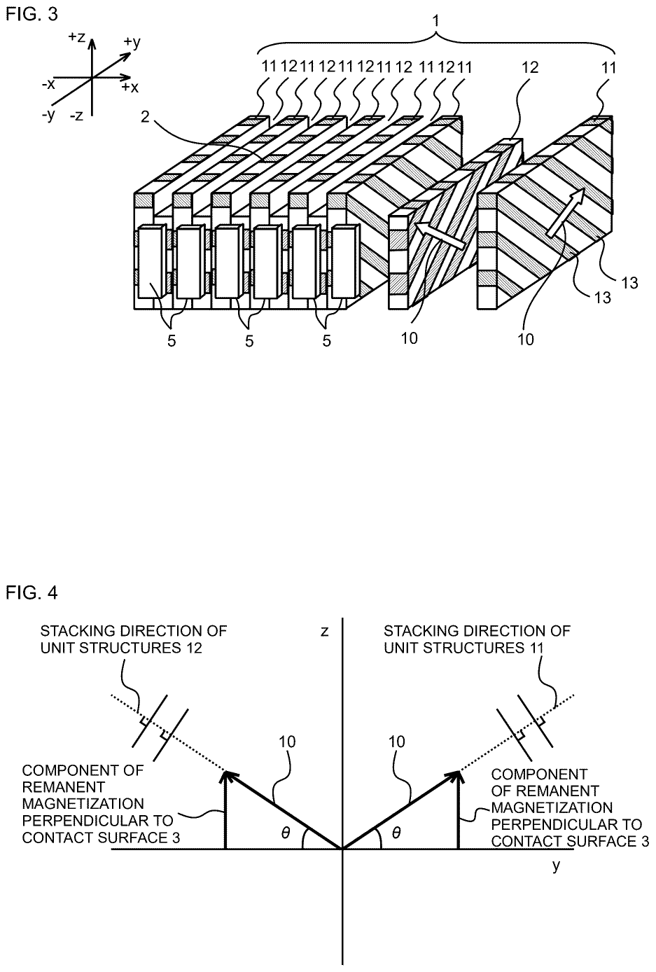

This makes it easy to form a heat dissipation structure.
[7] Tilted stack (FIG. 3)

The thermoelectric device described in [5] or [6], in which the unit structure has at least two types of thermoelectric materials stacked in a direction inclined relative to the direction perpendicular to the electrode surface, and one of the at least two thermoelectric materials is a magnetic material.

This allows even a high-performance thermoelectric device with a stacked tilted stack to integrate the heat dissipation structure and to be attached to an object by magnetic force.

### 2. Details of the Embodiments

The embodiments will now be described in further detail.

### First Embodiment

FIG. 1 is an explanatory diagram schematically illustrating a basic configuration of a thermoelectric device according to the present invention. The thermoelectric device according to the present invention comprises a bulk thermoelectric permanent magnet (i.e., a bulk of thermoelectric material with remanent magnetization) 1, a contact surface 3 for contacting an object (i.e., an −z plane of bulk 1; a plane orthogonal to the −z direction when bulk 1 is a rectangular body with its height extending in the z axis), heat dissipation surface 2 (i.e., a +z plane of bulk 1) opposite contact surface 3 across bulk thermoelectric permanent magnet 1, and electrode surface 4 that sandwich bulk thermoelectric permanent magnet 1 in a direction (+y/−y direction) different from those of contact surface 3 and heat dissipation surface 2. Heat dissipation surface 2 is a heat dissipation structure integrally structured with bulk thermoelectric permanent magnet 1.

This allows the heat flow to be efficiently concentrated on the thermoelectric material (i.e., bulk thermoelectric permanent magnet 1), thereby realizing a highly efficient thermoelectric conversion element. Contact surface 3 is brought into direct contact with a high-temperature object, and heat can be dissipated directly into the atmosphere or the like from the heat dissipation structure integrally formed with heat dissipation surface 2. Since no components other than the thermoelectric material, such as an electrode, a substrate, or a heat sink, are present in the path of the temperature gradient (heat flow) from the object to the atmosphere, etc., the entire temperature gradient is applied to the thermoelectric material.

Since the area of bulk thermoelectric permanent magnet 1 when viewed in plan view from the z-axis direction coincides with the heat flow path from contact surface 3 to heat dissipation surface 2, all of the heat flow contributes to thermoelectric conversion. As described above, the entire temperature gradient is applied to the thermoelectric material, so the heat flow does not include any thermal resistance source in series, and there is no parallel path that passes through anything other than the thermoelectric material, making it an ideal structure where all of the supplied thermal energy is supplied to the thermoelectric material and used for thermoelectric conversion.

Furthermore, the remanent magnetization of bulk thermoelectric permanent magnet 1 is suitable from the viewpoint of adhesion when it has a component perpendicular to contact surface 3. On the other hand, when the remanent magnetization has a component parallel to contact surface 3, there is an advantage that the thermoelectric power due to the anomalous Nernst effect in the bulk thermoelectric permanent magnet can be superimposed. The remanent magnetization of the bulk thermoelectric permanent magnet superimposes a magneto-thermoelectric effect on the thermoelectric material, and the same remanent magnetization can be used to magnetically attach the contact surface 3 to an object made of a magnetic metal such as iron, making the installation of the thermoelectric device extremely easy.

The heat dissipation structure has a surface area that is at least twice the area of heat dissipation surface 2 in plan view (the area when viewed from the +z side in the −z direction). This allows direct heat dissipation from the bulk thermoelectric permanent magnet 1 without going through an electrode, a substrate, a heat sink, etc. Here, the surface area means the area in contact with the medium to be dissipated. When the heat dissipation structure comes into contact with air, water, or other fluid, the heat transfer coefficient is increased, enabling efficient heat dissipation.

In addition, it is more suitable if contact surface 3 is also one surface of bulk thermoelectric permanent magnet 1 itself. This allows bulk thermoelectric permanent magnet 1 to be heated directly without going through an electrode, a substrate, a heat sink, etc. When adhering to a flat object, contact surface 3 of bulk thermoelectric permanent magnet 1 can be made flat and adhered to, thereby lowering the interfacial thermal resistance and heating the object efficiently. Here, “heating” does not mean active heating, but rather the transfer of heat from the object to bulk thermoelectric permanent magnet 1 via contact surface 3.

### Second Embodiment

FIG. 2 is an explanatory diagram schematically illustrating an example configuration of a thermoelectric device according to a second embodiment of the present invention.

As in the first embodiment, the thermoelectric device comprises a bulk thermoelectric permanent magnet (i.e., a bulk of thermoelectric material with remanent magnetization) 1, contact surface 3 (i.e., a −z surface of bulk 1) for contacting an object, heat dissipation surface 2 (i.e., a +z plane of bulk 1) opposite contact surface 3 across bulk thermoelectric permanent magnet 1, and electrode surface 4 that sandwich bulk thermoelectric permanent magnet 1 in a direction (+y/−y direction) different from those of contact surface 3 and heat dissipation surface 2. Heat dissipation surface 2 is a heat dissipation structure integrally structured with bulk thermoelectric permanent magnet 1. In the second embodiment, bulk thermoelectric permanent magnet 1 is composed of a plurality of unit structures 11, 12 arranged in a direction (+/−x direction) different from contact surface 3 (−z direction), heat dissipation surface 2 (+z direction), and electrode surfaces 4 (+/−y direction), while being electrically insulated, and the plurality of unit structures 11, 12 are electrically connected to each other at electrode surface 4. That is, a plurality of thermoelectric material unit structures 11 and 12 can be electrically connected in series alternately to increase the output voltage. The output voltage is maximized by designing the thermoelectric material so that a potential difference occurs between unit structures 11 and 12 in opposite directions relative to the temperature gradient in the z direction (for example, a potential difference occurs in the +y direction in unit structure 11 and in the −y direction in the unit structure 12).

In the second embodiment, the heat dissipation structure can be configured by unevenness formed by the lengths of unit structures 11 and 12. For example, as shown in FIG. 2, by making the height (length in the z direction) of unit structure 11 longer than the height (length in the z direction) of unit structure 12 and by bringing contact surface 3 into close contact with a planar object and arranging unit structures 11 and 12 in the x direction, unevenness is formed on heat dissipation surface 2 due to the difference in height between unit structures 11 and 12, and this functions as a heat dissipation structure.

This makes it easy to form a heat dissipation structure. Since unit structures 11 and 12 are generally sintered bodies of thermoelectric material, they are not suitable for processing into complex shapes by cutting or stamping. However, as shown in this embodiment, a heat dissipation structure can be constructed by making up unit structures 11 and 12 of rectangular parallelepipeds with only the height changed, and simply by arranging them alternately.

Unit structures 11 and 12 are bulk thermoelectric permanent magnets 1 with remanent magnetization as in the first embodiment, and the remanent magnetization is more suitable if it has a component perpendicular to contact surface 3. As in the first embodiment, the remanent magnetization of the bulk thermoelectric permanent magnet 1 can be used to magnetically attach contact surface 3 to an object made of a magnetic material such as iron, making the installation of the thermoelectric device extremely easy. In addition, since multiple unit structures 11 and 12 can be installed in an alternating arrangement, a thermoelectric device of any length can be constructed depending on the number of unit structures. In particular, since the adjustment can be made at the installation stage, it is extremely convenient in that it can be adjusted to suit the object at the installation site. Furthermore, when multiple unit structures 11 and 12 are arranged alternately, they may be placed in close contact with each other with an isolation layer having a conductive region and an insulating region sandwiched therebetween to form wiring between adjacent unit structures. At this time, if the remanent magnetization has not only a component perpendicular to contact surface 3 but also a component perpendicular to the stacking surface, the magnetic force can be used for the close contact.

### Third Embodiment

FIG. 3 is an explanatory diagram schematically illustrating an example configuration of a thermoelectric device according to a third embodiment of the present invention.

The thermoelectric device according to the third embodiment is basically the same as the thermoelectric devices according to the first and second embodiments above, and is particularly characterized in that the unit structure 11, 12 has at least two types of thermoelectric materials stacked in a direction inclined relative to the direction perpendicular to electrode surface 4, and that one of the at least two thermoelectric materials is a magnetic material. This makes it possible to configure a high-performance thermoelectric device in which tilted stacks are stacked, with an integrated heat dissipation structure, and which can be attached to an object by magnetic force. The additional configurations and effects thereof described for the first and second embodiments are applicable to the third embodiment as well.

FIG. 4 is an explanatory diagram of remanent magnetization. Regarding remanent magnetization 10 of unit structures 11 and 12 in the yz plane, remanent magnetization 10 of unit structure 11 is shown as a vector in the right quadrant and remanent magnetization 10 of unit structure 12 is shown as a vector in the left quadrant with the origin at the center. The origin is meaningless. Unit structure 11 is a stack of two types of thermoelectric materials including a magnetic thermoelectric material, and is stacked at a predetermined angle θ from the direction perpendicular to electrode surface 4 (y-axis direction (+y direction)). Unit structure 11 has remanent magnetization 10 in its stacking direction, and remanent magnetization 10 has a component perpendicular to contact surface 3. Unit structure 12 is also suitably a stack of two types of thermoelectric materials including a magnetic thermoelectric material, and is stacked at an angle (−y to −θ) opposite to the direction perpendicular to electrode surface 4 (y-axis direction). Unit structure 12 also has remanent magnetization 10 in its stacking direction, and remanent magnetization 10 has a component perpendicular to contact surface 3. In order to make unit structures 11 and 12 have a predetermined angle (θ) and an opposite angle (−y to −θ) from the direction perpendicular to electrode surface 4 (y-axis direction), it is sufficient to fabricate the same tilted stacks and arrange them flipped over (rotate 180°) around the z-axis.

### Example 1

As an example of the present invention, in order to evaluate the thermoelectric performance, a thermoelectric element was fabricated by stacking unit structures of tilted stacks, and its characteristics were evaluated.

### Material Preparation

A samarium cobalt (SmCo₅) magnet (20 mm diameter×0.5 mm thick, YX24 manufactured by MagFine Corporation) was demagnetized by heating in a vacuum at 800 °C for 40 minutes. A demagnetized SmCo₅ magnet and 1.05 g of p-type thermoelectric material bismuth antimony telluride Bi_{0.3}Sb_{1.7}Te₃ powder (manufactured by Toshima Manufacturing Co., Ltd., 3N, 200 μm mesh pass) were alternately stacked in a carbon die and pressed with a punch to obtain a multilayer compact. The standard condition for this multilayer compact was a minimum of 10 times and a maximum of 13 times stacking.

The multilayer compact was sintered in an atmosphere-controlled spark plasma sintering apparatus (SPS-212HFEG manufactured by Fuji Electronic Industrial Co., Ltd.) to obtain a bulk thermoelectric material. The sintering conditions were as follows: uniaxial pressurization of 30 MPa, 450 °C, and 20 minutes under a vacuum atmosphere created by an oil rotary pump.

### Module Processing

The bulk thermoelectric material obtained above was cut out using a diamond wire saw (DWS100 manufactured by EiResearch Co., Ltd.). A rectangular shaped tilted stack was obtained by cutting the bulk thermoelectric material at an angle of approximately 23° to the stacked surface of the SmCo₅ magnet and Bi_{0.3}Sb_{1.7}Te₃ to create a contact surface with the heat source, and cutting the bulk thermoelectric material into a rectangular shape out with this contact surface as a reference.

A magnetic field of 8T was applied to the stacking direction of this tilted stack using a pulse magnetic field generator (manufactured by Toei Scientific Industrial Co., Ltd.), thereby magnetizing the SmCo₅ magnet in the stacking direction. As a result, the angle between the magnetization direction and the direction perpendicular to the contact surface with the object is approximately 23°, and the bulk thermoelectric material has a remanent magnetization vector component perpendicular to the contact surface.

Next, the tilted stack was cut into a thin piece with a width of about 1.5 mm using the diamond wire saw, to form a unit structure. As in FIG. 3, one unit structure 11 and the other unit structure 12 rotated 180° around the z-axis were arranged in the x-direction and stacked. The direction of remanent magnetization is reversed in the y-axis direction and aligned in the z-axis direction, as shown in FIG. 4, so that the total remanent magnetization vector component is generated in the height direction for the entire stack.

Paper towels (manufactured by AS ONE Corporation) were placed between the unit structures as insulation layers, and a total of 13 unit structures were adhered together with instant adhesive (Aron Alpha Tough Power manufactured by Toagosei Co., Ltd.). Furthermore, as illustrated in FIGS. 3, 13 unit structures 11 and 12 were alternately connected to form an electrical series circuit by alternately wiring and connecting them to each other using electrodes 5 made of indium (manufactured by The Nilaco Corporation) formed on electrode surfaces 4 of the unit structures, thereby obtaining a bulk thermoelectric module.

In this Example, the heights of the unit structures 11 and 12 are the same, but by fabricating unit structures of different heights for various applications and stacking them alternately with the contact surfaces aligned, a heat dissipation structure is formed on the heat dissipation surface by the thermoelectric material of the tilted stack itself. To fabricate unit structures of different heights, various methods can be adopted, such as changing the height of the above-mentioned rectangular parallelepiped-shaped tilted stack and cutting out unit structures 11 and 12 from each, or, as described later in Example 2, cutting out a tall unit structure 11 from the above-mentioned rectangular parallelepiped-shaped tilted stack, and then lowering the height of the rectangular parallelepiped-shaped tilted stack using a diamond wire saw and cutting out a short unit structure 12.

### Measurement of Power Generation Performance

Copper wires (manufactured by The Nilaco Corporation) were connected to both ends of the electrical circuit of the fabricated bulk thermoelectric module, and the sides excluding the contact surface and the heat dissipation surface were fixed with a heat dissipation adhesive (COM-G52 manufactured by Com⋅Institute Inc). With a temperature difference ΔT applied between the contact surface and the heat dissipation surface, four-terminal DC electrical measurements were carried out on the two copper wires. The voltage V (V) was measured by sweeping the load current I_{load} (A), with one side of the copper wire defined as a positive voltage (V+) and a negative current (I−), and the other side as a negative voltage (V−) and a positive current (I+). The power generation output P(W) is expressed as the product of the load current I_{load} and the voltage V. The voltage V was measured by sweeping the load current I_{load} from 0 A to 1 A or 1.2 A under five different temperature differences ΔT (135 K, 109 K, 87 K, 61 K, and 42 K), the power generation output P was obtained.

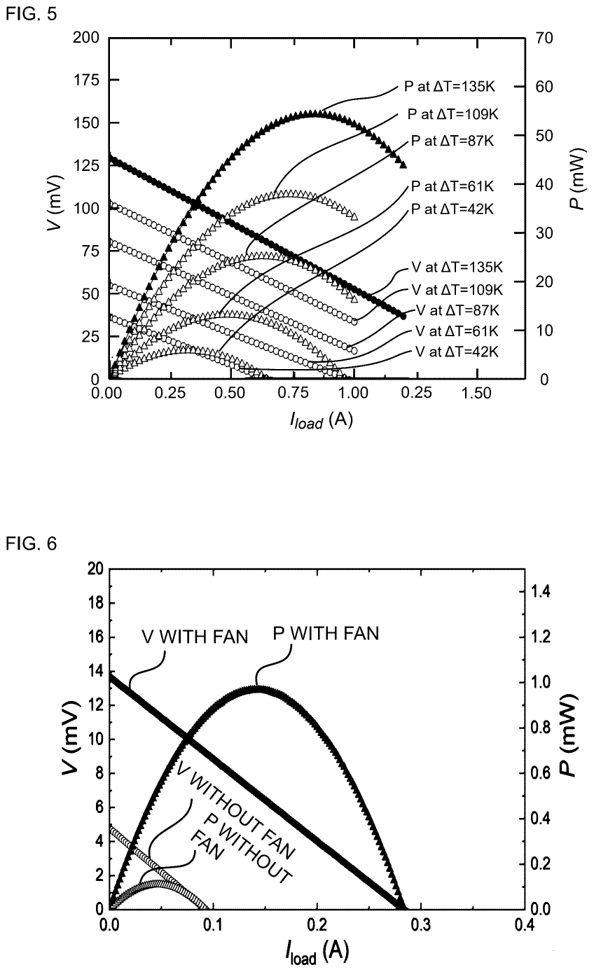

FIG. 5 is a graph showing the measurement results of the power generation performance of the bulk thermoelectric module fabricated as Example. The horizontal axis represents the swept load current, I_{load}, and the vertical axis represents the voltage, V on the left (left axis) and the power generated output P on the right (right axis). The circled plot represents the measured voltage V (left axis) and the triangular plot represents the power generation output P (right axis). For the maximum temperature difference ΔT=135 K, the plot is solid black, while the plots for other temperature differences are open.

The measurement results showed that at the maximum temperature difference ΔT=135 K, the maximum power generated was 54 mW. This value achieves more than 20 mW/cm² per unit contact area. This generated power per unit area is approximately twice that of the tilted stacked thermoelectric module shown in PTL 1.

### Example 2

As another example of the present invention, mainly to evaluate the heat dissipation performance, a thermoelectric element having an unevenness structure formed by the heights of a tilted stack was fabricated, and its characteristics were evaluated.

### Material Preparation

Since this is the same as Example 1 above, repeated explanations will be omitted.

### Module Processing

The bulk thermoelectric material obtained above was cut out using a diamond wire saw (DWS100 manufactured by EiResearch Co., Ltd.) as in Example 1. A rectangular shaped tilted stack was obtained by cutting the bulk thermoelectric material at an angle of approximately 23° to the stacked surface of the SmCo₅ magnet and Bi_{0.3}Sb_{1.7}Te₃ to create a contact surface with the heat source, and cutting the bulk thermoelectric material into a rectangular shape with a height of 8.4 mm and a length of 11.0 mm out with this contact surface as a reference.

Next, the tilted stack was cut into a thin piece with a width of about 1.5 mm using the diamond wire saw, to form a unit structure for a protruding part. This unit structure for a protruding part was cut to a height of 6.3 mm by the diamond wire saw to create a unit structure for a recessed part.

Paper towels (manufactured by AS ONE Corporation) were placed between the unit structures as insulation layers, and a total of eight unit structures (four recessed parts and four protruding parts) were adhered alternately using instant adhesive (Aron Alpha Tough Power, manufactured by Toagosei Co., Ltd.). By aligning the contact surfaces, the thermoelectric material of the tilted stack itself formed an uneven heat dissipation structure on the heat dissipation surface, measuring 2.1 mm in height, 1.5 mm in width, and spaced 1.5 mm apart. This heat dissipation structure has a surface area 2.4 times larger than that when viewed in plan.

Furthermore, as illustrated in FIG. 3, four unit structures for protruding parts (corresponding to unit structure 11 in FIG. 3) and four unit structures for recessed parts (corresponding to unit structure 12 in FIG. 3) were alternately connected to form an electrical series circuit by alternately wiring and connecting them to each other using electrodes 5 made of indium (manufactured by The Nilaco Corporation) formed on electrode surfaces 4 of the unit structures, thereby obtaining a bulk thermoelectric module. As in the bulk thermoelectric module of Example 1, one unit structure 11 and the other unit structure 12 rotated 180° around the z-axis were arranged in the x-direction and stacked.

A magnetic field of 8T was applied to the height direction of this tilted stack using a pulse magnetic field generator (manufactured by Toei Scientific Industrial Co., Ltd.), to magnetize it in the stacking direction, which is the easy axis of magnetization of the SmCo₅ magnet. As a result, the angle between the magnetization direction and the direction perpendicular to the contact surface with the object is approximately 27°, and the bulk thermoelectric material has a remanent magnetization vector component perpendicular to the contact surface. The direction of remanent magnetization is reversed in the y-axis direction and aligned in the z-axis direction, as shown in FIG. 4, so that the total remanent magnetization vector component is generated in the height direction for the entire stack.

### Measurement of Power Generation Performance

Copper wires (manufactured by The Nilaco Corporation) were connected to both ends of the electrical circuit of the fabricated bulk thermoelectric module and fixed with indium. The bulk thermoelectric module was magnetically attached to a stainless steel member via a high thermal conductivity heat dissipation sheet MANION (manufactured by Sekisui Polymatech Co., Ltd.), and the entire stainless steel member was heated on a hot plate. The voltage V was measured by sweeping the load current I_{load} under the condition that the heat dissipating part of the bulk thermoelectric module was air-cooled by natural convection and by forced convection by a blower, and the power generation output P was obtained.

FIG. 6 is a graph showing the measurement results of the power generation performance of the bulk thermoelectric module fabricated as Example 2. The horizontal axis represents the swept load current, I_{load}, and the vertical axis represents the voltage, V on the left (left axis) and the power generated output P on the right (right axis). The circled plot represents the measured voltage V (left axis) and the triangular plot represents the power generation output P (right axis). The plots with the fan are solid black, and those without the fan are open. The measurement results demonstrated air-cooled heat dissipation thermoelectric power generation of up to 1 mW with a fan.

The present invention made by the present inventors has been specifically described above based on the embodiments, but obviously, the present invention is not limited thereto and can be modified in various ways without departing from the spirit of the present invention.

### EXPLANATION OF SIGN

1 Bulk thermoelectric permanent magnet
2 Heat dissipation surface
3 Contact surface
4 Electrode surface
5 Electrode
10 Residual magnetic field
11, 12 Unit structure of thermoelectric materials

1. A thermoelectric device, comprising:
a bulk of thermoelectric material with remanent magnetization;
a contact surface for contacting an object;
a heat dissipation surface opposite the contact surface across the bulk; and
electrode surfaces that sandwich the bulk in a direction different from those of the contact surface and the heat dissipation surface,
wherein the heat dissipation surface is a heat dissipation structure integrally structured with the bulk,
wherein the remanent magnetization has a component perpendicular to the contact surface.

2. The thermoelectric device according to claim 1, wherein
the heat dissipation structure has a surface area that is at least twice the area of the heat dissipation surface viewed in plan view.

3. The thermoelectric device according to claim 1, wherein
the contact surface is a surface of the bulk.

4. The thermoelectric device according to claim 1, wherein
the bulk consists of a plurality of unit structures electrically isolated and arranged in the direction different from those of the contact surface, the heat dissipation surface and the electrode surface, the plurality of unit structures being electrically interconnected on the electrode surface.

5. The thermoelectric device according to claim 4, wherein
the heat dissipation structure is unevenness of the unit structure.

6. The thermoelectric device according to claim 5 wherein
the unit structure has at least two types of thermoelectric materials stacked in a direction inclined relative to the direction perpendicular to the electrode surface, and one of the at least two thermoelectric materials is a magnetic material.
